(19) United States
(12) Patent Application Publication
(10) Pub. No.: US 2016/0293444 A1
(43) Pub. Date: Oct. 6, 2016

(54) METHOD OF MANUFACTURING SEMICONDUCTOR DEVICE

(71) Applicant: SAMSUNG ELECTRONICS CO., LTD., Suwon-si (KR)

(72) Inventors: Jae-hong PARK, Seongnam-si (KR); Jun-ho YOON, Suwon-si (KR); Je-woo HAN, Hwaseong-si (KR); Gyung-jin MIN, Seongnam-si (KR); Dong-chan KIM, Seoul (KR); Kyung-yub JEON, Yongin-si (KR); Jin-young PARK, Anyang-si (KR)

(21) Appl. No.: 14/961,918

(22) Filed: Dec. 8, 2015

(30) Foreign Application Priority Data
Mar. 31, 2015 (KR) 10-2015-0045330

(51) Int. Cl. H01L 21/311; H01L 21/3205

(52) U.S. Cl. CPC H01L 21/31144; H01L 21/32051

(57) ABSTRACT

A method of manufacturing a semiconductor device, the method including forming an insulating layer on a substrate; forming a metallic hardmask pattern on the insulating layer; forming a recess by partially etching the insulating layer; forming a metallic protection layer on an inner side wall of the recess; etching the insulating layer to form a hole that penetrates the insulating layer by using the metallic hardmask pattern and the metallic protection layer as etching masks; and removing the metallic hardmask pattern and the metallic protection layer.

### CROSS-REFERENCE TO RELATED APPLICATION

Korean Patent Application No. 10-2015-0045330, filed on Mar. 31, 2015, in the Korean Intellectual Property Office, and entitled: “Method of Manufacturing Semiconductor Device,” is incorporated by reference herein in its entirety.

### BACKGROUND

1. Technical Field

Embodiments relate to a method of manufacturing a semiconductor device.

2. Description of the Related Art

As the integration of semiconductor devices increases, the design rules that apply to the components of semiconductor devices may decrease.

### SUMMARY

Embodiments may be realized by providing a method of manufacturing a semiconductor device. The method includes forming an insulating layer on a substrate; forming a metallic hardmask pattern on the insulating layer; forming a recess by partially etching the insulating layer; forming a metallic protection layer on an inner side wall of the recess; etching the insulating layer to form a hole that penetrates the insulating layer by using the metallic hardmask pattern and the metallic protection layer as etching and removing the metallic hardmask pattern and the metallic protection layer.

The metallic hardmask pattern may have an etching selectivity with respect to the insulating layer of at least 5:1.

The metallic hardmask pattern may include tungsten.

The metallic protection layer may include tungsten.

Etching the insulating layer and forming the metallic protection layer may be performed in an identical chamber of a semiconductor manufacturing apparatus.

Etching the insulating layer and forming the metallic protection layer may be performed by different semiconductor manufacturing apparatuses.

Forming the metallic protection layer on the inner side wall of the recess may include conformally forming the metallic protection layer along the inner side wall and a bottom surface of the recess; and removing the metallic protection layer formed on the bottom surface of the recess.

The insulating layer may include a silicon oxide layer or a silicon nitride layer or a silicone oxide layer and a silicon nitride layer that are alternately stacked on each other. Etching the insulating layer may include forming a polymer protection layer on an inner side wall of the hole while etching the insulating layer.

The insulating layer may include an element to be included in a three-dimensional memory device.

Embodiments may be realized by providing a method of manufacturing a semiconductor device. The method includes forming an insulating layer on a substrate; forming a metallic hardmask pattern on the insulating layer; forming a recess by partially etching the insulating layer; forming a metallic protection layer on an inner side wall of the recess in a chamber of a semiconductor manufacturing apparatus; and forming a hole that penetrates the insulating layer by etching the insulating layer in the chamber.

The method may further include, after forming the hole, removing the metallic hardmask pattern and the metallic protection layer.

Forming the hole may include forming a polymer protection layer on the inner side wall of the recess while etching the insulating layer.

A depth of the recess may be smaller than a half of a thickness of the insulating layer.

Each of the metallic hardmask pattern and the metallic protection layer may include tungsten.

Embodiments may be realized by providing a method of manufacturing a semiconductor device. The method includes forming an insulating layer on a substrate; forming a metallic hardmask pattern on the insulating layer; forming a recess by partially etching the insulating layer using the metallic hardmask pattern as an etching mask; forming a metallic protection layer on an inner side wall of the recess using a first semiconductor manufacturing apparatus; and forming a hole that penetrates the insulating layer by etching the insulating layer using a second semiconductor manufacturing apparatus that is different from the first semiconductor manufacturing apparatus.

The metallic hardmask pattern may include tungsten; and the insulating layer may include one or more of a silicon oxide layer or a silicon nitride layer.

The hole may have a ratio of a depth to a diameter of at least about 10:1.

Forming the hole may include partially etching the metallic protection layer.

The metallic protection layer may have an etching selectivity with respect to the insulating layer of at least about 5:1.

### BRIEF DESCRIPTION OF THE DRAWINGS

Features will become apparent to those of skill in the art by describing in detail example embodiments with reference to the attached drawings in which:

FIG. 1 illustrates a flowchart of a method of manufacturing a semiconductor device, according to an example embodiment;

FIGS. 2A and 2B illustrate views for describing a method of manufacturing a semiconductor device, according to a first comparative experimental embodiment of an example embodiment;

FIGS. 3A and 3B illustrate views for describing a method of manufacturing a semiconductor device, according to a second comparative experimental embodiment of an example embodiment;

FIGS. 4 through 9 illustrate views for describing a method of manufacturing a semiconductor device, according to an example embodiment;

FIG. 10 illustrates a diagram of a card including a semiconductor device manufactured by a method of manufacturing a semiconductor device according to example embodiments;

FIG. 11 illustrates a diagram of an electronic system including a semiconductor device manufactured by a method of manufacturing a semiconductor device according to example embodiments; and

FIG. 12 illustrates a perspective view of an electronic device including a semiconductor device manufactured by a method of manufacturing a semiconductor device according to example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. It will be understood that, although the terms “first”, “second,” “third,” etc., may be used herein to describe various elements, components, regions, layers, and/or sections, these elements, components, regions, layers, and/or sections should not be limited by these terms. These terms are only used to distinguish one element, component, region, layer, or section from another region, layer, or section. For example, a first element could be termed a second element, and, similarly, a second element could be termed a first element, without departing from the scope of example embodiments.

The terminology used herein is for describing particular embodiments and is not intended to be limiting of example embodiments. As used herein, the singular forms “a,” “an,” and “the,” are intended to include the plural forms as well, unless the context clearly displays otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meanings as commonly understood in the art to which the example embodiments belong. It will be further understood that the terms such as those defined in commonly used dictionaries should be interpreted as having meanings consistent with their meanings in the context of the relevant art and will not be interpreted in an idealized or overly formal sense unless expressly so defined herein.

In this specification, the term a “high aspect ratio” refers to a ratio of a depth to a width (or a diameter) that is equal to or greater than about 10:1, and the term a “high selectivity” denotes that an etching selectivity is equal to or greater than about 5:1. On the contrary, the term a “low aspect ratio” refers to a ratio of a depth to a width (or a diameter) that is less than about 10:1, and the term a “low selectivity” denotes that an etching selectivity is less than about 5:1.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

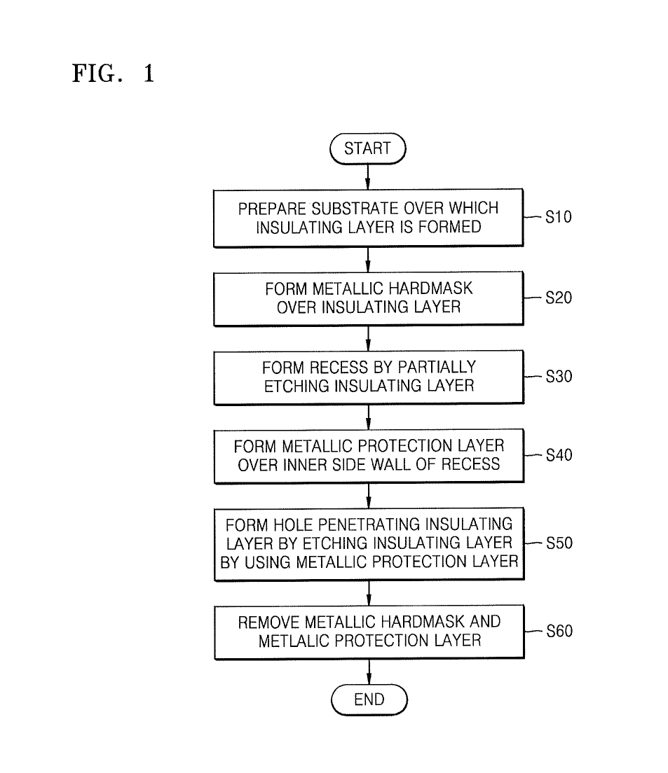

Hereinafter, example embodiments will be described in detail by referring to FIGS. 1 through 12.

FIG. 1 illustrates a flowchart of a method of manufacturing a semiconductor device, according to an example embodiment.

The method of manufacturing the semiconductor device according to the present example embodiment may include preparing a substrate over which an insulating layer is formed in operation S10, forming a metallic hardmask pattern over the insulating layer in operation S20, forming a recess by partially etching the insulating layer in operation S30, forming a metallic protection layer over an inner side wall of the recess in operation S40, forming a hole that penetrates the insulating layer by etching the insulating layer by using the metallic protection layer in operation S50, and removing the metallic hardmask pattern and the metallic protection layer in operation S60.

A sequential order of processes to form a contact hole having a high aspect ratio in the insulating layer will be described in detail.

In operation S10, the substrate over which the insulating layer is formed is prepared. The substrate may be a substrate that may be used for manufacturing a semiconductor device, and may be a semiconductor integrated circuit. The semiconductor integrated circuit may include at least one selected from a transistor, a diode, a capacitor, and a resistor. In operation S20, the metallic hardmask pattern with high selectivity may be formed over the insulating layer and the hardmask pattern may be patterned by a light exposure method to form an opening having a desired diameter.

In operation S30, the recess is formed in the insulating layer by partially etching the insulating layer, and in operation S40, the metallic protection layer is formed on the side wall of the recess to prevent the occurrence of a bowing phenomenon when the insulating layer is etched to form the hole. The metallic protection layer may include tungsten (W) or a tungsten-based metal material, which may have a high etching selectivity with respect to the insulating layer. The metallic protection layer may be formed by using any one of an atomic layer deposition (ALD) method, a chemical vapor deposition (CVD) method, and a physical vapor deposition (PVD) method, which use a tungsten fluoride (WₓF_{y}, for example, WF₆)-based gas.

An in-situ method may be used to form the metallic protection layer by using the tungsten fluoride-based gas. Etching the insulating layer may be stopped in the first chamber and the first chamber may be used to form the metallic protection layer.

As an example, an ex-situ method may be used whereby the metallic protection layer may be formed by using a second semiconductor manufacturing apparatus including a chamber for forming the metallic protection layer, which may be separate from a first semiconductor manufacturing apparatus including the etching chamber in which the insulating layer may be etched.

A thickness of the metallic protection layer may protect a side wall of the hole during the sequential etching process, and the thickness may be formed to be equal to or less than 10 nm, and a speed of the sequential etching process may not be affected.

Next, a bottom surface of the metallic protection layer is etched before the sequential etching of the insulating layer is performed. To remove the bottom surface of the metallic protection layer, the etching may be performed by applying a high bias power thereto and using a chlorine (Cl₂)-based gas.

Thereafter, the insulating layer is etched to a desired depth by the sequential etching process, and the hole penetrating the insulating layer is formed. Since a side surface portion of the hole in which a bowing phenomenon may occur is protected by the metallic protection layer, a vertical shape of the side surface portion of the hole may be maintained when etching the insulating layer in operation S50.

Lastly, after etching the insulating layer to form the contact hole having a high aspect ratio is completed, the remaining metallic hardmask pattern and the remaining metallic protection layer are removed, and the contact hole in which the bowing phenomenon is prevented from occurring is completely manufactured in operation S60. Operations S30 through S50 may be repeatedly performed at least more than two times according to an etching time and a desired depth of the contact hole.

According to an example embodiment, the process may be performed such that the metallic protection layer may not be formed on the bottom surface of the recess. When the metallic protection layer is not formed on the bottom surface of the recess, the sequential etching of the insulating layer may be directly performed without the process of etching the metallic protection layer formed on the bottom surface of the recess.

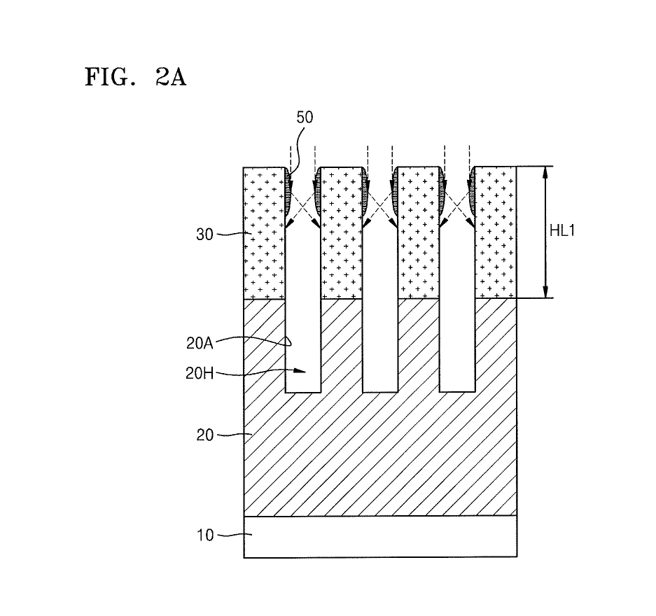

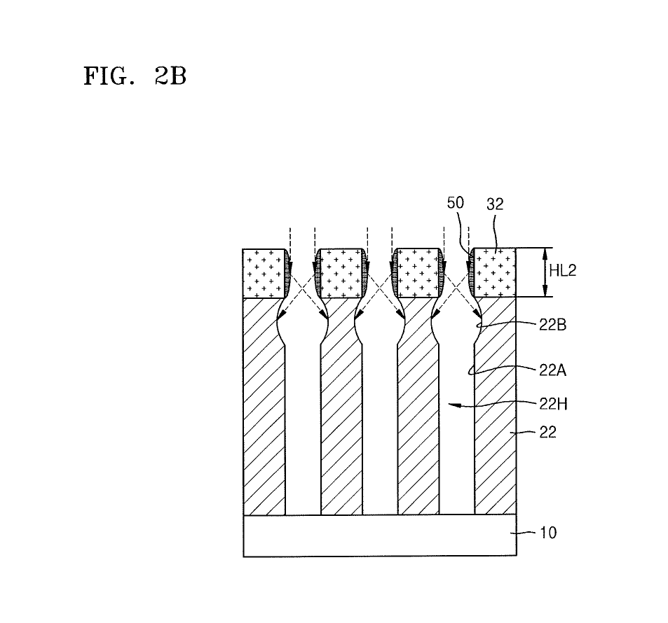

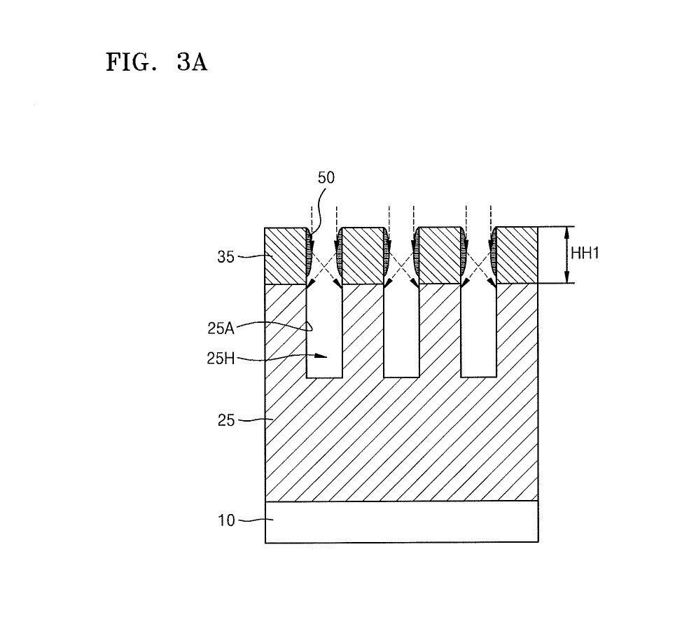

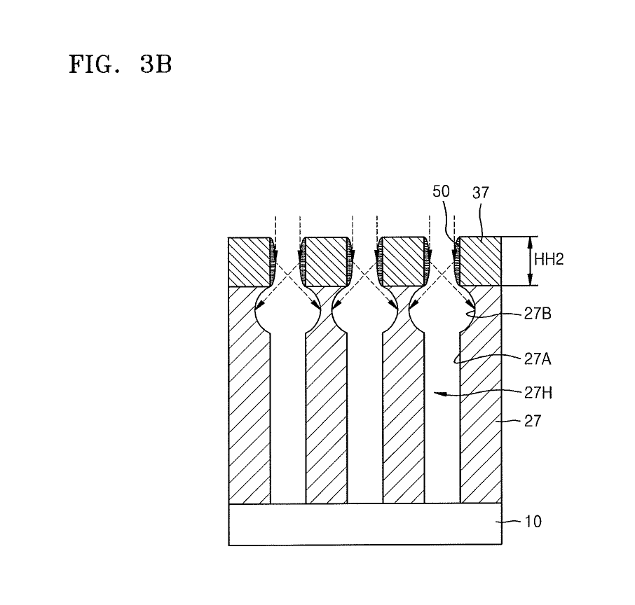

FIGS. 2A and 2B illustrate views for describing a method of manufacturing a semiconductor device, according to a first comparative experimental embodiment of an example embodiment, and FIGS. 3A and 3B illustrate views for describing a method of manufacturing a semiconductor device, according to a second comparative experimental embodiment of an example embodiment;

While the insulating layer is etched to form the contact hole having a high aspect ratio, electric charges may accumulate along a side wall of a hole which may have a small width and a great depth and linearity of ions that flow into the hole may be affected by a polymer protection layer in the etching process, and ion scattering may occur. Due to, for example, the ion scattering, undesired etching may be performed on the side wall of the hole, the hole may not be formed to have a complete vertical shape and may be curved or twisted, and a short may occur between contact structures. This phenomenon is referred to as a bowing phenomenon. In FIGS. 2A, 2B, 3A, and 3B, the ion scattering is indicated via dotted lined arrows.

FIGS. 2A and 2B illustrate a case in which a contact hole having a high aspect ratio is etched by using a hardmask pattern 30 with low selectivity, according to the first comparative experimental embodiment.

FIG. 2A illustrates a shape of an insulating layer 20 from an initial point of etching to a middle point of etching. When the insulating layer 20 is etched by using the hardmask pattern 30 with low selectivity, the hardmask pattern 30 with low selectivity which has a relatively great thickness HL1 is used due to a low etching selectivity with respect to the insulating layer 20, and thus, ion scattering may occur on a side wall of the hardmask pattern 30 with low selectivity, without occurring on a side wall 20A of a hole 20H formed in the insulating layer 20, from the initial point of etching to the middle point of etching.

FIG. 2B illustrates a shape of an insulating layer 22 from a middle point of etching to a late point of etching. In this process, a hardmask pattern 32 with low selectivity is also etched so that the hardmask pattern 32 with low selectivity has a small thickness HL2, and thus, ion scattering occurs on a side wall 22A of a hole 22H formed in the insulating layer 22 after the middle point of etching. Thus, since the side wall 22A of the hole 22H may be etched to a predetermined depth, a bowing phenomenon causing a round shape 22B may occur. However, since ion scattering does not occur through the whole etching process for forming the contact hole, on the side wall 22A of the hole 22H formed in the insulating layer 22, a short of contact structures due to the bowing phenomenon may not occur.

FIGS. 3A and 3B illustrate a case in which a contact hole having a high aspect ratio is etched by using a hardmask pattern 35 with high selectivity without using the metallic protection layer, according to the second comparative experimental embodiment.

FIG. 3A illustrates a shape of an insulating layer 25 from an initial point of etching to a middle point of etching. Unlike the first comparative experimental embodiment when the insulating layer 20 is etched from the initial point of etching to the middle point of etching, ion scattering may occur on a side wall 25A of a hole 2511 formed in the insulating layer 25. For example, in the case of the hardmask pattern 35 with high selectivity, a thickness reduction of the hardmask pattern 35 with high selectivity is relatively less than that of the hardmask pattern (30 of FIG. 2A) with low selectivity during etching the insulating layer 25, and thus, the hardmask pattern 35 with high selectivity is formed to have a small thickness HH1. Accordingly, ion scattering occurs on the side wall 25A of the hole 25H formed in the insulating layer 25 from an initial point of etching.

FIG. 3B illustrates a shape of an insulating layer 27 from a middle point of etching to a late point of etching. Even from the middle point of etching to the late point of etching of the insulating layer 27, a thickness HH2 of a hardmask pattern 37 with high selectivity changes less compared to the hardmask pattern (32 of FIG. 2B) with low selectivity, and thus, ion scattering may still occur on a side wall 27A of a hole 27H formed in the insulating layer 27. Thus, the side wall 27A of the hole 27H may be etched to a predetermined depth so that a bowing phenomenon of a round shape 27B may occur. Since the ion scattering occurs on the side wall 27A of the hole 27H formed in the insulating layer 27 throughout the overall etching process, a short between contact structures may occur due to the bowing phenomenon.

However, when the contact hole having a high aspect ratio is etched by using the hardmask pattern (30 of FIG. 2A) with low selectivity, it is technically hard to pattern the hardmask pattern (30 of FIG. 2A) with low selectivity, and precisely transferring a pattern shape on the insulating layer to be etched may be hard too. Accordingly, the hardmask pattern 35 with high selectivity, with respect to the insulating layer, may be used when etching the contact hole having a high aspect ratio. It may be easier to pattern the hardmask pattern 35 with high selectivity by using a light exposure process than the hardmask pattern (30 of FIG. 2A) with low selectivity. However, when using the hardmask pattern 35 with high selectivity, the bowing phenomenon may occur. According to embodiments, there is provided a method of manufacturing a semiconductor device whereby the occurrence of a bowing phenomenon may be prevented.

According to embodiments, there is provided the method of manufacturing the semiconductor device whereby the occurrence of bowing phenomenon when forming the contact hole having a high aspect ratio by using the hardmask pattern 35 with high selectivity may be reduced. The method may include forming a metallic protection layer which may protect the side wall 25A of the hole 25H before performing a sequential etching process.

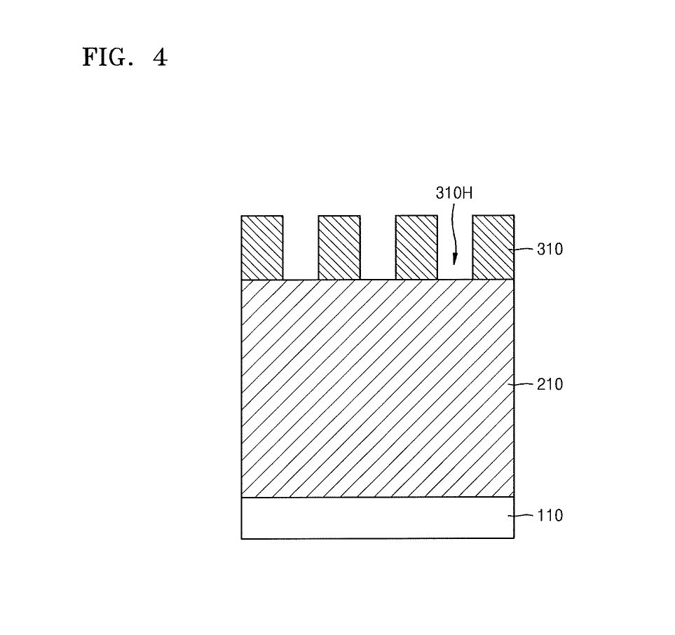

FIGS. 4 through 9 illustrate views for describing a method of manufacturing a semiconductor device according to an example embodiment.

FIG. 4 illustrates that an insulating layer 210 may be formed on a substrate 110 and a metallic hardmask pattern 310 may be formed on the insulating layer 210.

The substrate 110 may be a bulk silicon (Si) substrate or a silicon on insulator (SOI) substrate. The substrate 110 may include silicon, for example, crystalline silicon, polycrystalline silicon, or amorphous silicon. In some embodiments, the substrate 110 may include germanium (Ge) or a compound semiconductor, such as silicon germanium (SiGe) and silicon carbide (SiC). The substrate 110 may include a semiconductor integrated circuit. The semiconductor integrated circuit may include at least one selected from a transistor, a diode, a capacitor, and a resistor.

As illustrated in FIG. 4, the metallic hardmask pattern 310 may be formed on the insulating layer 210. The metallic hardmask pattern 310 may have an opening 310H to etch the below insulating layer 210. The insulating layer 210 may be a silicon oxide (SiₓO_{y}) layer or a silicon nitride (SiₓN_{y}) layer or may include a silicon oxide (SiₓO_{y}) layer and a silicon nitride (SiₓN_{y}) layer which may be alternately stacked. The insulating layer 210 may be an interlayer dielectric (ILD), an inter-metal dielectric (IMD), or a device separation layer of a three-dimensional memory device, according to a method by which the insulating layer 210 is formed and the use of the insulating layer 210.

The metallic hardmask pattern 310 may include a material having a high etching selectivity with respect to the insulating layer 210, for example, a material with high selectivity. Various metals and/or metallic materials may be used. According to the present example embodiment, the metallic hardmask pattern 310 may include tungsten (W).

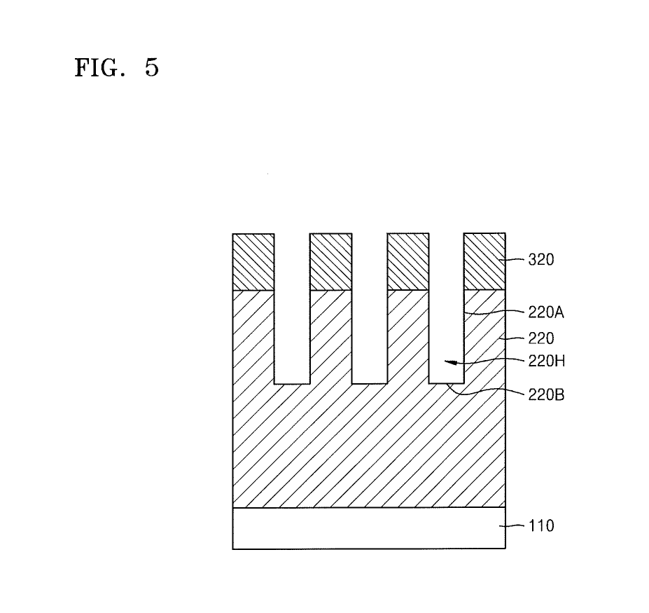

FIG. 5 illustrates that a recess 220H may be formed by partially etching an insulating layer 220 by using the metallic hardmask pattern 320.

While forming the recess 220H by partially etching the insulating layer 220, a bowing phenomenon may also occur. However, in an early etching stage, an effect of the bowing phenomenon on a side wall 220A of the recess 220H may be small. However, as the recess 220H is etched to a greater depth in, e.g., over, time, the effect of the bowing phenomenon may become great, and the etching process may be performed such that the recess 220H formed by partially etching the insulating layer 220 may have a depth that is equal to or less than a half of a thickness of the insulating layer 220 that is to be etched.

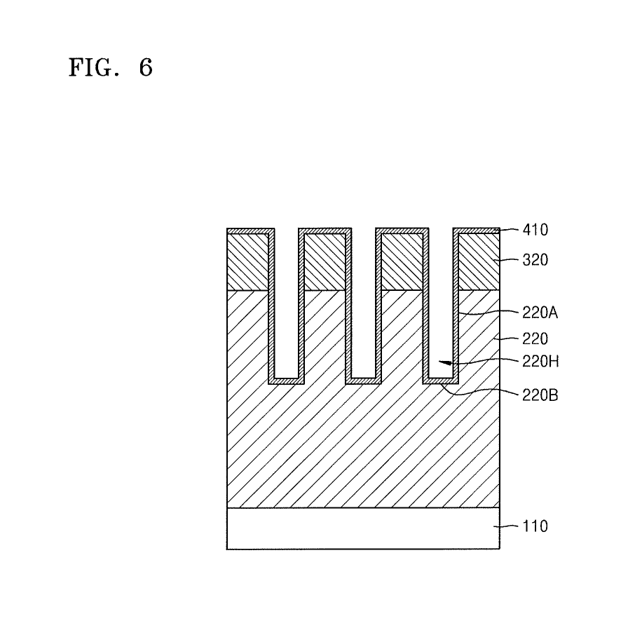

The etching process may be performed in a first chamber. Not only etching the insulating layer 220, but also forming of a metallic protection layer (410 of FIG. 6) may be performed in the first chamber.

FIG. 6 illustrates that the metallic protection layer 410 may be conformally formed in the recess 220H formed by partially etching the insulating layer 220.

The metallic protection layer 410 may be conformally formed in the recess 220H to prevent the occurrence of a bowing phenomenon when the contact hole having a high aspect ratio is etched. The metallic protection layer 410 may be conformally formed also on the metallic hardmask pattern 320. The metallic protection layer 410 may include a material having a high etching selectivity with respect to the insulating layer 220, such as tungsten (W), and may be formed by using an ALD method or a CVD method, wherein a tungsten fluoride (WₓF_{y}, for example, WF₆) gas may be used.

In an embodiment, a PVD method may be used based on a step coverage difference to form the metallic protection layer 410 in order to prevent the metallic protection layer 410 from being formed on a bottom surface 220B of the recess 220H.

A process of forming the metallic protection layer 410 may be performed such that the metallic protection layer 410 may not be formed on the bottom surface 220B of the contact hole due to, for example, a step coverage difference used in each of the above methods of forming the metallic protection layer 410. An additional etching process of the metallic protection layer 410 formed on the bottom surface 220B of the recess 220H may not be necessary.

The metallic protection layer 410 may be formed by using an in-situ method whereby etching the insulating layer 220 to form the recess 220H may be stopped in the first chamber and the first chamber may be used to form the metallic protection layer 410.

As an example, the metallic protection layer 410 may be formed by using an ex-situ method whereby the metallic protection layer 410 may be formed by using a second semiconductor manufacturing apparatus including a chamber for forming the metallic protection layer 410, which may be separate from a first semiconductor manufacturing apparatus including the etching chamber in which the insulating layer 220 may be etched to form the recess 220H.

When the in-situ method is used, the etching and the thin film forming processes may be performed in one chamber without having to shift the substrate 110 to different chambers, and the substrate 110 may be prevented from being polluted by air.

As an example, when the ex-situ method is used, the etching and the thin film forming processes may be performed in different semiconductor manufacturing devices, a previous process and a sequential process may be completely separated, and effects of the previous and sequential processes on each other may be minimized.

A thickness of the metallic protection layer 410 may protect the side wall 220A of the recess 220H during the sequential etching process and may be formed to be equal to or less than 10 nm, and a speed of sequential etching may not be affected.

When manufacturing a semiconductor device having a highly reduced size, a diameter of a contact hole may be less than 50 nm. If the metallic protection layer 410 is formed to be excessively thick on the side wall 220A of the recess 220H, performing the etching process may be hard. Thus, according to a decrease of the diameter of the contact hole, the thickness of the metallic protection layer 410 may be reduced. However, when the metallic protection layer 410 is formed to be too thin, the metallic protection layer 410 may hardly protect the side wall 220A of the recess 220H, which is the objective of forming the metallic protection layer 410, and the thickness of the metallic protection layer 410 may be determined according to a diameter of the contact hole that is to be formed.

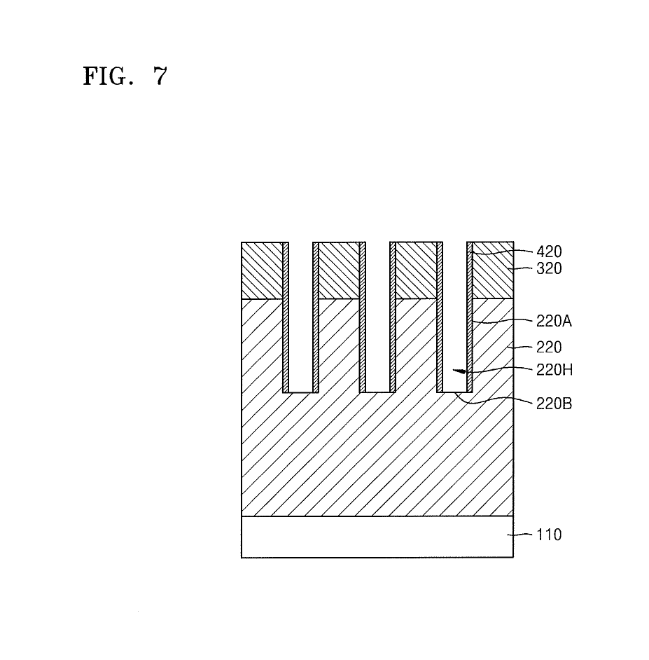

FIG. 7 illustrates that a metallic protection layer 420 may be formed on the side wall 220A of the recess 220H.

Referring to FIGS. 6 and 7 together, after the metallic protection layer 410 is formed, the metallic protection layer 410 formed on the bottom surface 220B of the recess 220H may be removed in order to sequentially perform etching the insulating layer 220. To remove the metallic protection layer 410 formed on the bottom surface 220B of the recess 220H, the metallic protection layer 410 may be etched by applying thereto a high bias power and using a chlorine (Cl₂)-based gas. To remove the metallic protection layer 410 formed on the bottom surface 220B of the recess 220H while keeping the metallic protection layer 420 formed on the side wall 220A of the recess 220H, a high bias power may be applied, etching ions may be generated, and the etching process may be performed with high straightness, e.g., having a high aspect ratio. To remove the metallic protection layer 410 formed on the bottom surface 220B of the recess 220H while not affecting other semiconductor layers formed on the substrate 110, a chlorine (Cl₂)-based gas for removing a tungsten-based material may be used.

In this process, the metallic protection layer 410 formed on an upper surface of the metallic hardmask pattern 320 may be removed. Although it is illustrated in FIG. 7 that the metallic protection layer 410 formed on the upper surface of the metallic hardmask pattern 320 is completely removed, the metallic protection layer 410 may remain on the upper surface of the metallic hardmask pattern 320 since the present process is for removing the metallic protection layer 410 formed on the bottom surface 220B of the recess 220H.

In other embodiments, the process of forming the metallic protection layer 420 may be performed by using a step coverage difference such that the metallic protection layer 420 may be formed only on the side wall 220A of the recess 220H. The process of removing the metallic protection layer 410 formed on the bottom surface 220B of the recess 220H may not be necessary.

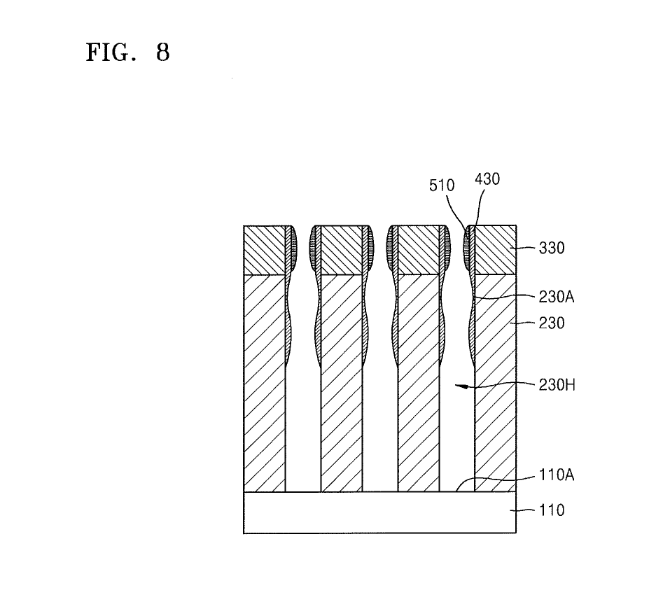

FIG. 8 illustrates that a hole 230H may be formed to penetrate an insulating layer 230 to expose a portion of an upper surface 110A of the substrate 110.

An additional etching process may be performed in a state in which a metallic protection layer 430 may be formed on a portion of a side wall 230A of the hole 230H. A portion of the metallic protection layer 430 may be changed to have a round shape due to, for example, ion scattering. The metallic protection layer 430 may prevent the occurrence of a bowing phenomenon on the side wall 230A of the hole 230H due to, for example, the ion scattering. As described above, a thickness of the metallic protection layer 430 may be adjusted in consideration of a diameter of the contact hole such that the side wall 230A of the hole 230H may not be etched even when the metallic protection layer 430 is partially etched due to, for example, an etching selectivity of the metallic protection layer 430 with respect to the insulating layer 230.

A polymer-based by-product may be generated when etching the insulating layer 230, and the process may be performed such that the by-product may be formed as a polymer protection layer 510 on the side wall 230A of the hole 230H, and the polymer protection layer 510 may be formed in the hole 230H or on a surface of the metallic protection layer 430. The polymer protection layer 510 may have a lower etching selectivity with respect to the insulating layer 230 than the metallic protection layer 430, for example, the polymer protection layer 510 may include a material having a low selectivity. Thus, when etching the contact hole having a high aspect ratio as in example embodiments, the polymer protection layer 510 alone may not sufficiently protect the side wall 230A of the hole 230H. However, according to the example embodiments, the metallic protection layer 430 may be primarily formed on the side wall 230A of the hole 230H and the polymer protection layer 510 may be secondarily formed on the metallic protection layer 430, and a double protection layer including the polymer protection layer 510 and the metallic protection layer 430 may further reduce the occurrence of the bowing phenomenon on the side wall 230A of the hole 230H.

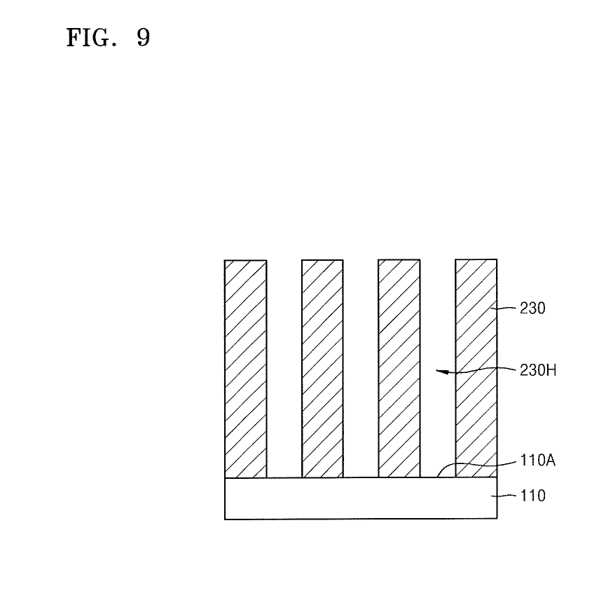

FIG. 9 illustrates that both of a metallic hardmask pattern (330 of FIG. 8) formed on an upper surface of the insulating layer 230 and the metallic protection layer 430 formed on the side wall 230A of the penetrating hole 230H may be removed.

When the hole 230H is formed to penetrate the insulating layer 230 by etching the insulating layer 230 to a bottom portion thereof, the contact hole having a high aspect ratio may be completely formed by removing the metallic hardmask pattern (330 of FIG. 8) and the metallic protection layer (430 of FIG. 8).

The etching and the thin film forming processes described above may be performed repeatedly at least more than two times according to an etching time and a depth of the contact hole. For example, in the case of a contact hole having a very high aspect ratio, forming the metallic protection layer once may not sufficiently prevent the occurrence of the bowing phenomenon, and forming of the metallic protection layer may be performed several times, according to necessity.

Accordingly, according to the method of manufacturing the semiconductor device according to the example embodiments, the occurrence of a bowing phenomenon when forming the contact hole having a high aspect ratio by using a hardmask pattern with high selectivity may be prevented, and the yield rate and the reliability of the semiconductor device may be improved.

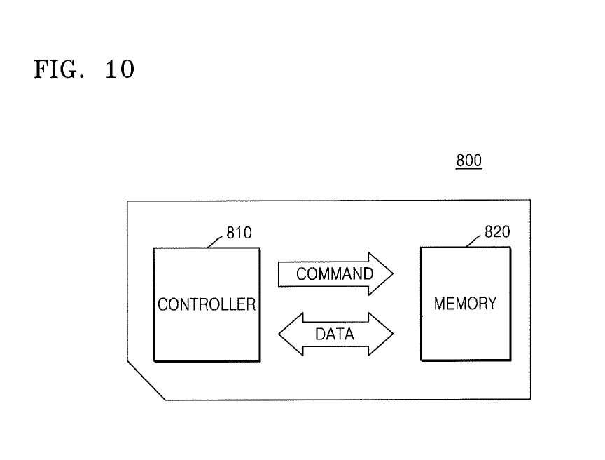

FIG. 10 illustrates a diagram of a card 800 including a semiconductor device manufactured by the method of manufacturing the semiconductor device according to the example embodiments.

A controller 810 and a memory 820 of the card 800 may be arranged to exchange electrical signals. For example, when the controller 810 outputs a command, the memory 820 may transmit data. The memory 820 or the controller 810 may include the semiconductor device manufactured by the method of manufacturing the semiconductor device according to the example embodiments. The card 800 may be of types, for example, a memory stick card, a smart media (SM) card, a secure digital (SD) card, a mini secure digital (mini SD) card, or a multi media card (MMC).

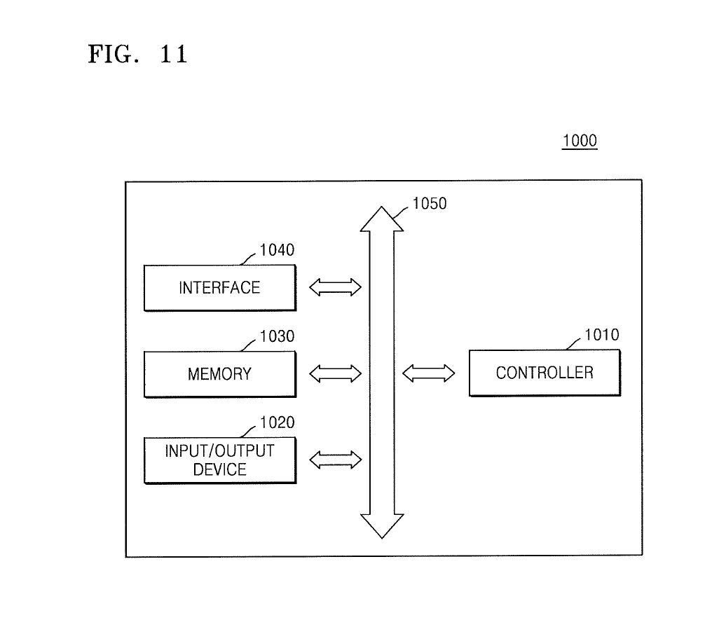

FIG. 11 illustrates a diagram of an electronic system 1000 including a semiconductor device manufactured by the method of manufacturing the semiconductor device according to the example embodiments.

The electronic system 1000 may include a controller 1010, an input/output device 1020, a memory 1030, and an interface 1040. The electronic system 1000 may be a mobile system or a system for transmitting or receiving information. The mobile system may be a personal digital assistant (PDA), a portable computer, a web tablet, a wireless phone, a mobile phone, a digital music player, or a memory card.

The controller 1010 may execute a program and control the system 1100. The controller 1010 may include the semiconductor device manufactured by the method of manufacturing the semiconductor device according to the example embodiments. The controller 1010 may be, for example, a microprocessor, a digital signal processor, a microcontroller, or similar devices.

The input/output device 120 may be used for inputting or outputting data with regard to the electronic system 1000. The electronic system 1000 may be connected to an external device, for example, a personal computer or a network, by using the input/output device 1020 in order to exchange data with the external device. For example, the input/output device 1020 may be a keypad, a keyboard, or a display.

The memory 1030 may store a code and/or data for an operation of the controller 1110 and/or may store data processed by the controller 1110. The memory 1030 may include the semiconductor device manufactured by the method of manufacturing the semiconductor device according to the example embodiments. The interface 1040 may be a data transferring path between the electronic system 1000 and other external devices. The controller 1010, the input/output device 1020, the memory 1030, and the interface 1040 may communicate with one another via a bus 1050.

The electronic system 1000 may be used, for example, in a mobile phone, an MP3 player, navigation, a portable multimedia player (PMP), a solid state disk (SSD), or household appliances.

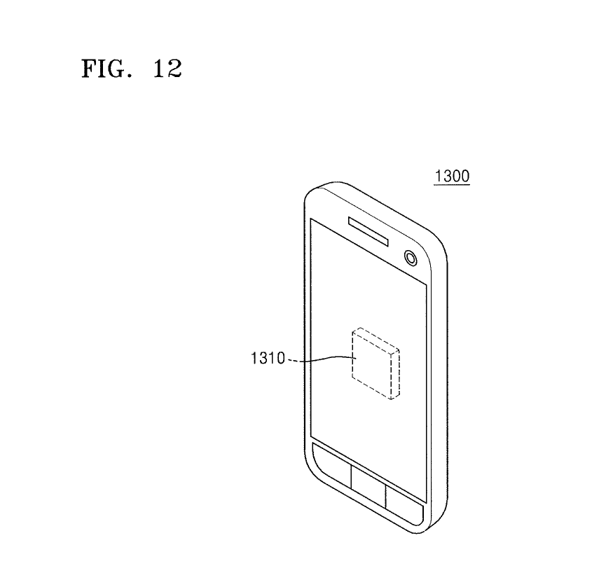

FIG. 12 illustrates a perspective view of an electronic device including a semiconductor device manufactured by the method of manufacturing the semiconductor device according to the example embodiments.

FIG. 12 illustrates in detail an example in which the electronic system 1000 may be applied to a mobile phone 1300. The mobile phone 1300 may include a system on chip (SOC) 1310. The SOC 1310 may include the semiconductor device manufactured by the method of manufacturing the semiconductor device according to the example embodiments, the mobile phone 1300 may include the SOC 1310 in which a relatively high performance main function block may be arranged, and the mobile phone 1300 may have relatively high performance.

Since the SOC 1310 may have relatively high performance even when an area thereof is small, the dimensions of the mobile phone 1300 including the SOC 130 may be minimized and the mobile phone 1300 may have relatively high performance.

The example embodiments include a three dimensional memory semiconductor device. The three-dimensional memory device may be formed as a monolithic structure including an active area on a silicon substrate and memory cell arrays having circuits related to operations of memory cells, the circuits being formed on the substrate or in the substrate. The term “monolithic” denotes that a layer of each level of the arrays is stacked directly above a layer of a right below level of the arrays.

In the example embodiments, the three-dimensional memory device may include vertical NAND strings so that at least one memory cell is located on another memory cell. The at least one memory cell may include a charge trap layer. Three-dimensional memory arrays may be formed as a plurality of levels that share word lines and/or bit lines.

By way of summation and review, in a process of forming a contact hole in a highly integrated semiconductor device, a bowing phenomenon may occur, and forming a contact hole in such a highly integrated semiconductor device may be more complicated and difficult than in a comparative semiconductor device.

Embodiments provide a method of manufacturing a semiconductor device, whereby the occurrence of a bowing phenomenon during forming a contact hole, e.g., with a high aspect ratio, in an insulating layer, may be reduced by using a hardmask pattern with high selectivity and forming a metallic protection layer, which may protect a side wall of the contact hole while the insulating layer is etched to form a contact hole having a high aspect ratio, and sequentially performing the etching process.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a semiconductor device, the method comprising:
forming an insulating layer on a substrate;
forming a metallic hardmask pattern on the insulating layer;
forming a recess by partially etching the insulating layer;
forming a metallic protection layer on an inner side wall of the recess;
etching the insulating layer to form a hole that penetrates the insulating layer by using the metallic hardmask pattern and the metallic protection layer as etching masks; and
removing the metallic hardmask pattern and the metallic protection layer.

2. The method as claimed in claim 1, wherein the metallic hardmask pattern has an etching selectivity with respect to the insulating layer of at least 5:1.

3. The method as claimed in claim 1, wherein the metallic hardmask pattern includes tungsten.

4. The method as claimed in claim 1, wherein the metallic protection layer includes tungsten.

5. The method as claimed in claim 1, wherein etching the insulating layer and forming the metallic protection layer are performed in an identical chamber of a semiconductor manufacturing apparatus.

6. The method as claimed in claim 1, wherein etching the insulating layer and forming the metallic protection layer are performed by different semiconductor manufacturing apparatus.

7. The method as claimed in claim 1, wherein forming the metallic protection layer on the inner side wall of the recess includes:
conformally forming the metallic protection layer along the inner side wall and a bottom surface of the recess; and
removing the metallic protection layer formed on the bottom surface of the recess.

8. The method as claimed in claim 1, wherein the insulating layer includes a silicon oxide layer or a silicon nitride layer or a silicone oxide layer and a silicon nitride layer that are alternately stacked on each other.

9. The method as claimed in claim 1, wherein etching the insulating layer includes forming a polymer protection layer on an inner side wall of the hole while etching the insulating layer.

10. The method as claimed in claim 1, wherein the insulating layer includes an element to be included in a three-dimensional memory device.

11. A method of manufacturing a semiconductor device, the method comprising:
forming an insulating layer on a substrate;
forming a metallic hardmask pattern on the insulating layer;
forming a recess by partially etching the insulating layer;
forming a metallic protection layer on an inner side wall of the recess in a chamber of a semiconductor manufacturing apparatus; and
forming a hole that penetrates the insulating layer by etching the insulating layer in the chamber.

12. The method as claimed in claim 11, further comprising, after forming the hole, removing the metallic hardmask pattern and the metallic protection layer.

13. The method as claimed in claim 11, wherein forming the hole includes forming a polymer protection layer on the inner side wall of the recess while etching the insulating layer.

14. The method as claimed in claim 11, wherein a depth of the recess is smaller than a half of a thickness of the insulating layer.

15. The method as claimed in claim 11, wherein each of the metallic hardmask pattern and the metallic protection layer includes tungsten.

16. A method of manufacturing a semiconductor device, the method comprising:
forming an insulating layer on a substrate;
forming a metallic hardmask pattern on the insulating layer;
forming a recess by partially etching the insulating layer using the metallic hardmask pattern as an etching mask;
forming a metallic protection layer on an inner side wall of the recess using a first semiconductor manufacturing apparatus; and
forming a hole that penetrates the insulating layer by etching the insulating layer using a second semiconductor manufacturing apparatus that is different from the first semiconductor manufacturing apparatus.

17. The method as claimed in claim 16, wherein:
the metallic hardmask pattern includes tungsten; and
the insulating layer includes one or more of a silicon oxide layer or a silicon nitride layer.

18. The method as claimed in claim 16, wherein the hole has a ratio of a depth to a diameter of at least about 10:1.

19. The method as claimed in claim 11, wherein forming the hole includes partially etching the metallic protection layer.

20. The method as claimed in claim 19, wherein the metallic protection layer has an etching selectivity with respect to the insulating layer of at least about 5:1.
